(19) United States
(12) Patent Application Publication
(10) Pub. No.: US 2008/0211076 A1
(43) Pub. Date: Sep. 4, 2008

(54) SEMICONDUCTOR DEVICE AND MANUFACTURING METHOD THEREOF

(75) Inventors: Hideo Nishiuchi, Kawasaki-shi (JP); Takeshi Miyagi, Fujisawa-shi (JP); Kazuki Tateyama, Yokohama-shi (JP); Susumu Obata, Yokohama-shi (JP); Kazuhito Higuchi, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 12/040,209

(22) Filed: Feb. 29, 2008

(30) Foreign Application Priority Data
Mar. 1, 2007 (JP) P2007-051309

(51) Int. Cl. H01L 23/04; H01L 21/00

(52) U.S. Cl. 257/684; 438/121; 257/E23.181; 257/E21.001

(57) ABSTRACT

A semiconductor device capable of elevating a yield rate of products to improve the productivity and also ensuring high reliability in production and a manufacturing method of the semiconductor device are provided. The semiconductor device includes a semiconductor substrate 2, a MEMS part 3 formed on a surface of the semiconductor substrate 2 and a cap part arranged at a distance from the MEMS part 3 and also arranged on the surface of the semiconductor substrate 2 so as to cover the MEMS part 3. In the semiconductor device, the cap part is formed by a sidewall area E surrounding the MEMS part 3 and a top board area F having a hollow layer and also forming a closed space together with the semiconductor substrate 2 and the sidewall area E.

### BACKGROUND OF THE INVENTION

1. Field of the Invention

The present invention relates to a semiconductor device having a MEMS part formed on a surface of a semiconductor substrate, and more particularly, the semiconductor device having a structure for sealing up the MEMS part. In addition, the present invention relates to a manufacturing method of such a semiconductor device.

2. Description of Related Art

A variety of micro machines have been recently utilized in many industrial fields. Correspondingly, micro-fabrication technique, so-called MEMS (Micro Electro Mechanical System) technique has been developed. Japanese Patent Publication Laid-open No. 2006-147995 discloses one method for manufacturing a semiconductor device where a MEMS device by use of this technique is connected to a substrate of the device.

According to the disclosed method, a vessel structure is firstly formed on a semiconductor substrate. The vessel structure comprises a sidewall frame adapted so as to surround the circumference of a desired area on the semiconductor substrate and a plate-type ceiling wall supported on the sidewall frame to oppose the surface of the substrate. Then, a variable displacement element having movable electrodes is arranged inside the vessel structure. The semiconductor device is manufactured by sealing the variable displacement element in the vessel structure. With the adoption of the manufacturing method, it becomes possible to eliminate the mechanical positioning of an exclusive structure for sealing the variable displacement element as well as the possibility of handling the so-completed semiconductor device in the same manner as an ordinary semiconductor device. Thus, because of the possibility of sealing the element by only a well-understood semiconductor manufacturing process with high accuracy of dimension, it is regarded that the disclosed manufacturing method could provide a semiconductor device with a further compact and thin variable displacement element.

There is also another manufacturing method of a semiconductor device 100 as shown in FIGS. 1 to 6. That is, a substrate 101 having a silicon oxide film 101b (as an insulating film) formed on a silicon substrate 101a is first prepared and successively, a MEMS device 102 is connected to the substrate 101. Then, on the substrate 101, a sacrificial layer 103 is arranged so as to cover the MEMS device 102, as shown in FIG. 2. For instance, polyimide or the like is usable for the sacrificial layer 103.

Further, as shown in FIG. 3, appropriate material, such as poly silicon, is laminated on the sacrificial layer 103 and the substrate 10 to form a first cap layer 104 thereon. In this state, the MEMS device 102 is covered with the sacrificial layer 103 and the first cap layer 104. Additionally, through-holes 105 are formed so as to penetrate the first cap layer 104 up to the sacrificial layer 103.

Thereafter, the sacrificial layer 103 covering the MEMS device 102 is removed from the substrate 101 through the through-holes 105 (see FIG. 4). Thus, the first cap layer 104 is positioned apart from the MEMS device 102 at a distance. Next, a second cap layer 106 is formed on the first cap layer 104. The second cap layer 106 is made of material identical to or different from that of the first cap layer 104. Then, the through-holes 105 are closed up by the second cap layer 106, as shown in FIG. 5.

Subsequently, electrode parts 107 are formed so as to penetrate the first cap layer 104 and the second cap layer 106 and additionally, resinous material 108 is molded so as to cover the second cap layer 106, completing a semiconductor device 100, as shown in FIG. 23.

### SUMMARY OF THE INVENTION

However, the above-mentioned manufacturing methods disclosed in the Publication Laid-open No. 2006-147995 and described with reference to FIGS. 1 to 6 have common problems to be solved, as follows.

Suppose, for instance, a MEMS device is utilized as one switch on a semiconductor substrate. Then, a space has to be ensured between the MEMS device 102 and the first cap layer 104 in order to effect the function of a switch (i.e. sealing with a hollow part). Additionally, if the MEMS device 102 is large-sized in the horizontal direction, the first cap layer 104 has to be large-sized correspondingly. However, if such a broadening of the first cap layer 104 is promoted furthermore, the enlargement would cause its shape to be maintained with difficulty.

For commercialization of product, additionally, there is a need of molding a product shape in resinous material in view of coping with disturbance. As anticipated, both of the above-mentioned manufacturing methods include a step of molding a product shape in the resinous material 108 commonly. Considering a general molding process using resinous material, however, it should be noted that a fill pressure in filling the resinous material into a molding die rises no fewer than 100 MPa, for instance. Therefore, depending on the structure of the cap layers, there is a possibility that the cap layers become unendurable to this filling pressure. In such a case, as no space is ensured between the MEMS device 102 and the first cap layer 104, the MEMS device 102 may be damaged disadvantageously.

According to the later manufacturing method, meanwhile, the semiconductor device is provided with dome-shaped cap layers 104 and 105, as shown in FIGS. 1 to 6. In actual, however, it is remarkably difficult to mold the sacrificial layer 103 in the form of a dome, which is required to complete the dome-shaped cap layer 104.

In order to define an airtight space containing the MEMS part 102, the first cap layer 104 is covered with the second cap layer 106 to clog up through-holes 105. However, there is a possibility that fluid material for the second cap layer 106 unfortunately flows into a space defined by the first cap layer 104 through the through-holes 105. In the worst case, such an inflow of material causes the MEMS device 102 to deteriorate in its characteristics.

In the above-mentioned situation, it is an object of the present invention to provide a semiconductor device equipped with a MEMS part, which is capable of elevating a yield rate of products to thereby improve the productivity and also ensuring high reliability in production. Further, it is also another object of the present invention to provide a manufacturing method of the so-improved semiconductor device.

In order to attain the former object, according to a first aspect of the present invention, there is provided a semiconductor device comprising: a semiconductor substrate; a MEMS part formed on a surface of the semiconductor substrate; and a cap part arranged at a distance from the MEMS part and also arranged on the surface of the semiconductor substrate so as to cover the MEMS part, wherein the cap part is formed by a sidewall area surrounding the MEMS part and a top board area having a hollow layer and also forming a closed space together with the semiconductor substrate and the sidewall area.

In order to attain the latter object, according to a second aspect of the present invention, there is also provided a manufacturing method of a semiconductor device having a semiconductor substrate and a MEMS part formed on a surface of the semiconductor substrate, the method comprising the steps of: forming a first sacrificial layer on the semiconductor substrate so as to cover both the MEMS part and a semiconductor substrate's part surrounding the MEMS part; forming a first cap layer so as to cover the first sacrificial layer and a semiconductor substrate's part surrounding the first sacrificial layer; forming at least one first through-hole in the first cap layer so as to penetrate the first cap layer and reach the first sacrificial layer; forming a second sacrificial layer on the first cap layer so as to oppose the MEMS part through the intermediary of the first cap layer, the second sacrificial layer communicating with the first sacrificial layer through the first through-hole; forming a second cap layer so as to cover the first cap layer and the second sacrificial layer; forming at least one second through-hole in the second cap layer so as to penetrate the second cap layer and reach the second sacrificial layer; removing the first sacrificial layer and the second sacrificial layer from the semiconductor device through the first through-hole and the second through-hole; and clogging the second through-hole.

### BRIEF DESCRIPTION OF THE DRAWINGS

FIG. 1 is a sectional view of a semiconductor device, explaining a first step of a conventional manufacturing method of the semiconductor device;

FIG. 2 is a sectional view of the semiconductor device, explaining a second step of the conventional manufacturing method;

FIG. 3 is a sectional view of the semiconductor device, explaining a third step of the conventional manufacturing method;

FIG. 4 is a sectional view of the semiconductor device, explaining a fourth step of the conventional manufacturing method;

FIG. 5 is a sectional view of the semiconductor device, explaining a fifth step of the conventional manufacturing method;

FIG. 6 is a sectional view of the semiconductor device, explaining a sixth step of the conventional manufacturing method;

FIG. 7 is a perspective view showing an overall semiconductor device in accordance with an embodiment of the present invention;

FIG. 8 is a sectional view of the semiconductor device, taken along a line A-A of FIG. 7;

FIG. 9 is a sectional view of the semiconductor device, taken along a line B-B of FIG. 7;

FIG. 10 is a sectional view of a semiconductor device, explaining a first step of a manufacturing method in accordance with the embodiment of the present invention;

FIG. 11 is a sectional view of a semiconductor device, explaining a second step of the manufacturing method in accordance with the embodiment of the present invention;

FIG. 12 is a sectional view of a semiconductor device, explaining a third step of the manufacturing method in accordance with the embodiment of the present invention;

FIG. 13 is a sectional view of a semiconductor device, explaining a fourth step of the manufacturing method in accordance with the embodiment of the present invention;

FIG. 14 is a sectional view of a semiconductor device, explaining a fifth step of the manufacturing method in accordance with the embodiment of the present invention;

FIG. 15 is a sectional view of a semiconductor device, explaining a sixth step of the manufacturing method in accordance with the embodiment of the present invention;

FIG. 16 is a sectional view of a semiconductor device, explaining a seventh step of the manufacturing method in accordance with the embodiment of the present invention;

FIG. 17 is a sectional view of a semiconductor device, explaining an eighth step of the manufacturing method in accordance with the embodiment of the present invention;

FIG. 18 is a sectional view of a semiconductor device, explaining a ninth step of the manufacturing method in accordance with the embodiment of the present invention;

FIG. 19 is a perspective view of an overall semiconductor device, showing the positions of first and second through-holes in the device;

FIG. 20 is a sectional view of a semiconductor device, supposing various dimensions of respective parts for calculations related to the semiconductor device in accordance with the embodiment of the present invention;

FIG. 21 is a graph exhibiting results of the calculations related to the semiconductor device in accordance with the embodiment of the present invention;

FIG. 22 is a perspective sectional view showing one example of a cap layer in the semiconductor device in accordance with the embodiment of the present invention; and

FIG. 23 is a perspective sectional view showing another example of the cap layer in the semiconductor device in accordance with the embodiment of the present invention.

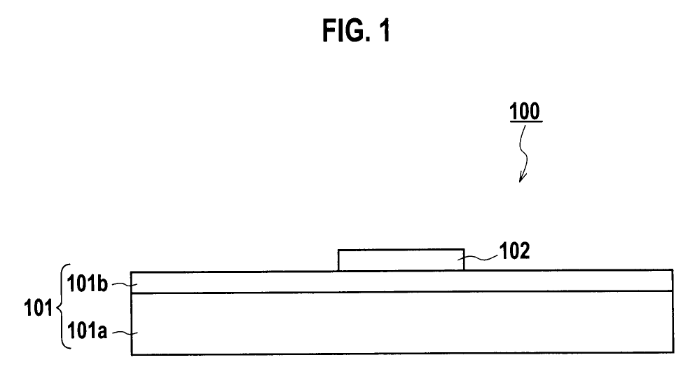

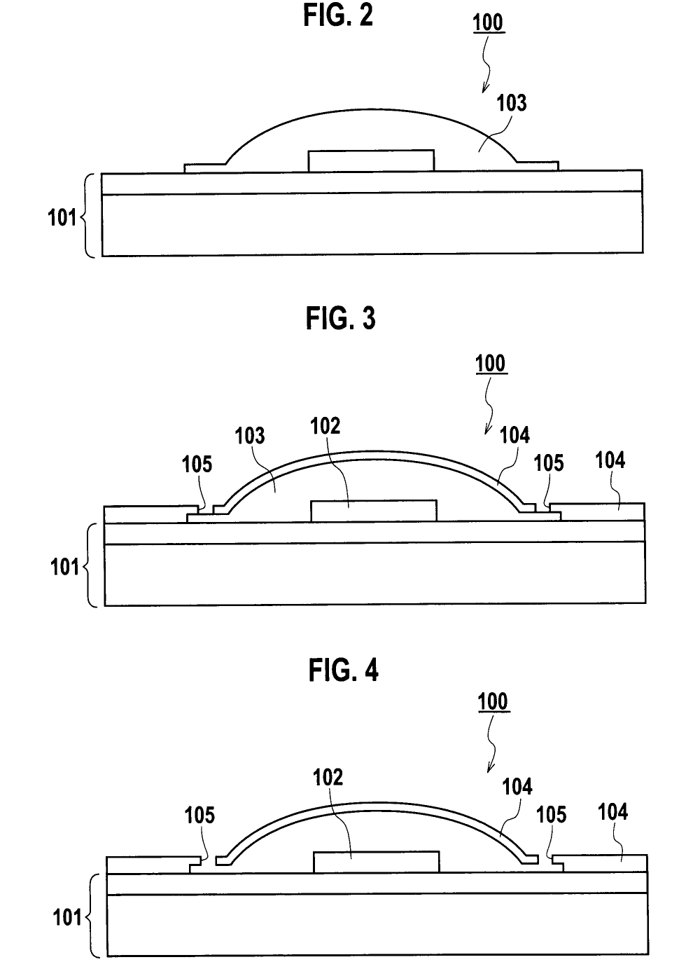

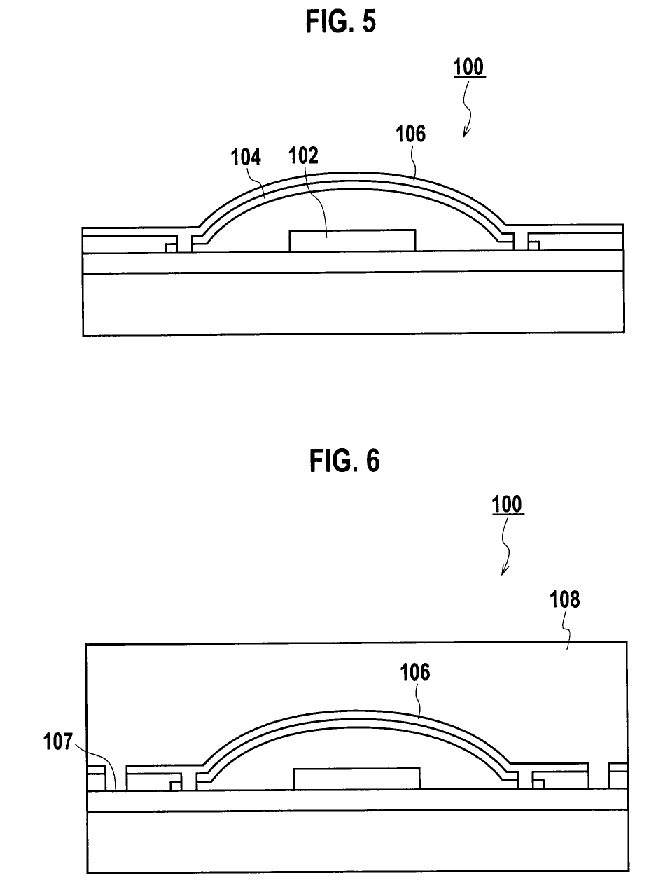

### DETAILED DESCRIPTION OF THE PREFERRED EMBODIMENTS

An embodiment of the present invention will be described with reference to attached drawings.

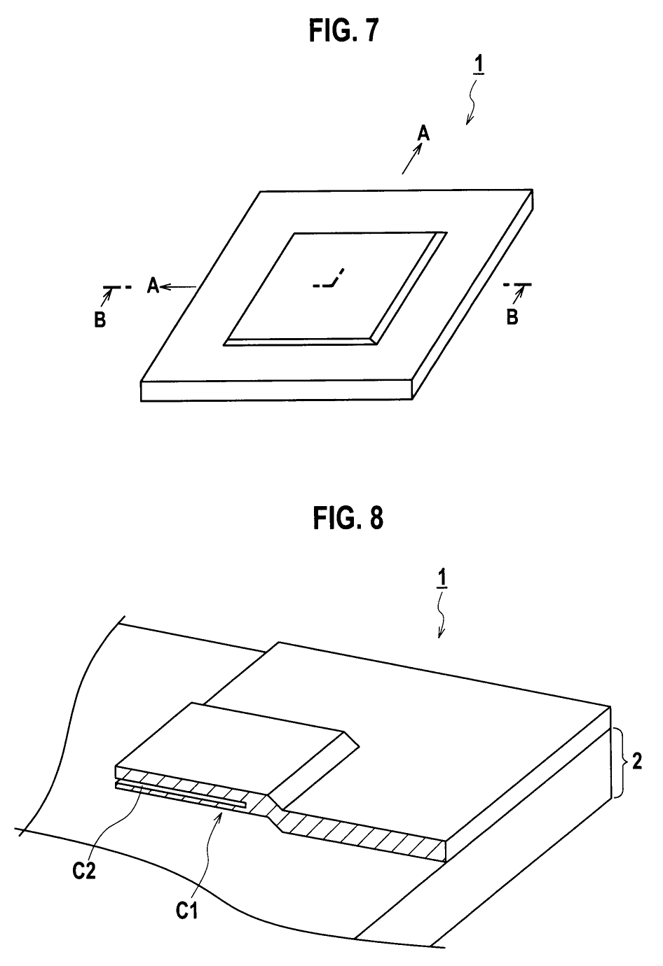

FIG. 7 shows an overall semiconductor device 1 in accordance with the embodiment of the present invention. In the semiconductor device 1, a semiconductor substrate 2 is formed, at its central area, with a bulge for ensuring a space for storing a MEMS part mentioned later.

FIG. 8 is a sectional view of the semiconductor device 1, taken along a line A-A of FIG. 7. More particularly, FIG. 8 is a sectional view of a cap part formed on the semiconductor substrate 2, illustrating a cross-sectional face shown with oblique lines. Note, the MEMS part to be connected onto the semiconductor substrate 2 is not shown in FIG. 8. The cap part includes a space C1 for storing the MEMS part at a central area of the semiconductor substrate 2. Further, as shown in FIG. 8, the cap part is provided with a hollow layer C2.

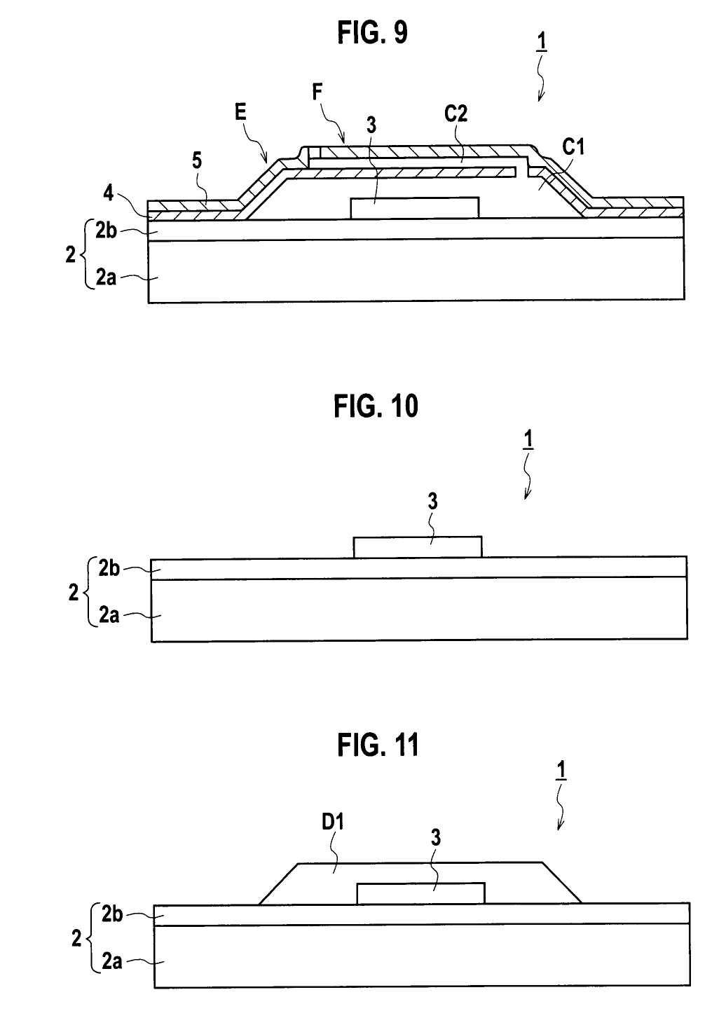

FIG. 3 is a sectional view of the semiconductor device 1, taken along line B-B of FIG. 7. The semiconductor substrate 2 comprises a substrate body 2a and an insulating film 2b applied on the whole upper surface of the substrate body 2a. The insulating film 2b may be either a passivation film (last protective film) or a resist layer. In the former case, for instance, the passivation film is formed by a composite membrane consisting of a dense-membranous silicon nitride film by the plasma CVD method and a polyimide, in lamination. In the latter case, for instance, the resist layer is identical to solder resist containing e.g. epoxy resin as the principal component. On the principle surface of the semiconductor substrate 2, there are various elements (e.g. transistors, resistances, capacitances, etc.) and wires for connecting between the elements to build up an integrated circuit, although they are not shown in FIG. 9.

On the semiconductor substrate 2, the MEMS part 3 is formed in the central area. For instance, the MEMS part 3 comprises a silicon semiconductor substrate and an aluminum conductive later laid on the substrate, although the manufacturing process of the MEMS part 3 is not described here.

On the semiconductor substrate 2, additionally, a first cap layer 4 is arranged apart from the MEMS part 3. In this way, the space C1 is ensured in the semiconductor device 1. The space C1 is sealed up in an airtight manner so as to allow the MEMS part 3 to exhibit its characteristics.

A second cap layer 5 is arranged so as to cover the first cap layer 4. Thus, both the first cap layer 4 and the second layer 5 are formed by a sidewall area E surrounding the circumference of the MEMS part 3 and a top board area F defining a closed space together with the semiconductor substrate 2 and the sidewall area E. Meanwhile, if the MEMS part 3 is formed with a greater width in the horizontal direction, then the cap part would have to be broader correspondingly. The above-mentioned double layer cap part composed of the first cap layer 4 and the second cap layer 5 is directed to prevention of a reduction in the strength of the top board area F due to the broader cap part. In this way, it is possible to protect the MEMS part 3 more certainly.

In the top board area F, a hollow layer C2 is defined between the first cap layer 4 and the second cap layer 5. The hollow layer C2 is provided for the purpose of dispersing a force applied on the second cap layer (part) 5 in the top board area F.

The manufacturing method of the semiconductor device 1 will be described with reference to FIGS. 10 to 18.

First, the substrate body 2a is prepared and successively, the insulating layer 2b is applied on the whole upper surface of the substrate body 2a, as shown in FIG. 10. For instance, the substrate body 2a is made of glass epoxy, monocrystal silicon or the like. The above-mentioned MEMS part 3 is formed on the semiconductor substrate 2.

Thereafter, a first sacrificial layer D1 is formed on the semiconductor substrate 2 so as to cover the MEMS part 3 (see FIG. 11). The first sacrificial layer D1 is temporarily provided to define the above space C1. Therefore, the first sacrificial layer D1 coincides with the above space C1 in terms of shape. In this embodiment, the first sacrificial layer D1 is shaped to have a trapezoidal section while covering the MEMS part 3 on the ground of easy-molding. Preferably, appropriate material, such as polyimide, is available for the first sacrificial layer D1.

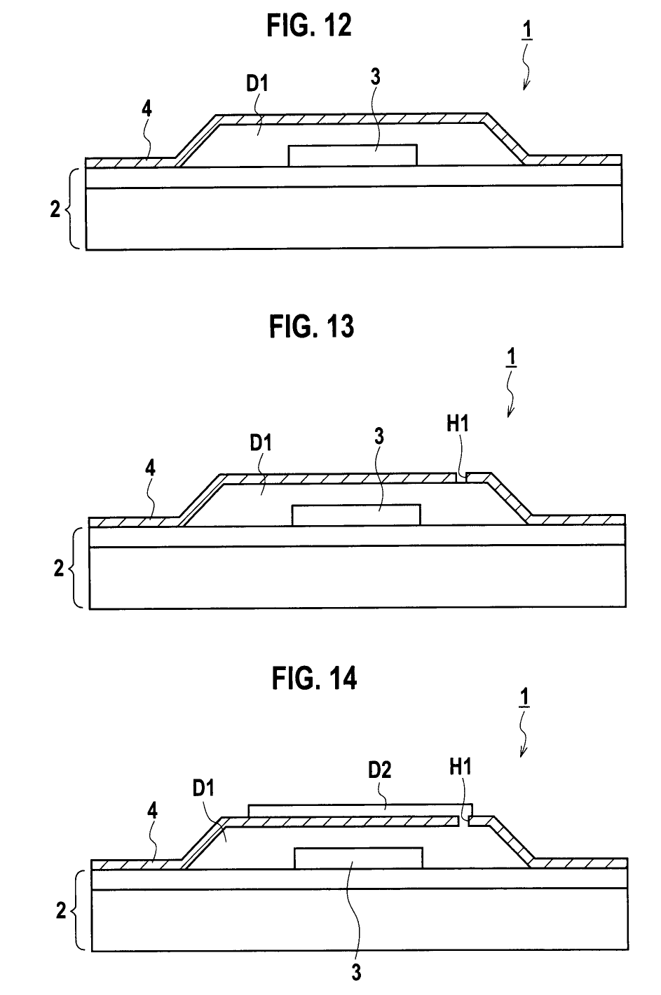

Next, as shown in FIG. 12, the first cap layer 4 is formed so as to cover the whole area of the semiconductor substrate 2 while covering the first sacrificial layer D1. Preferably, for instance, aluminum etc. is usable for the first cap layer 4. In the top board area F, a plurality of first through-holes H1 are formed in the first cap layer 4 in contact with the first sacrificial layer D1. Instead, a single through-hole may be formed in the first cap layer 4, although it is provided with the plurality of though-holes H1 in the illustrate embodiment (see FIG. 19).

In succession, a second sacrificial layer D2 is formed on the first cap layer 4 while filling in the first through-holes H1, as shown in FIG. 14. As a result, the second sacrificial layer D2 is brought into contact with the first sacrificial layer D1 through the first through-holes H1. The second sacrificial layer D2 is temporarily provided to define the above hollow space C2. In the embodiment of the present invention, as shown in FIG. 14, the second sacrificial layer D2 is formed so as to have an oblong cross section. The second sacrificial layer D2 may be made of the same material as the first sacrificial layer D1. Alternatively, the second sacrificial layer D2 may be made of different material from the first sacrificial layer D1.

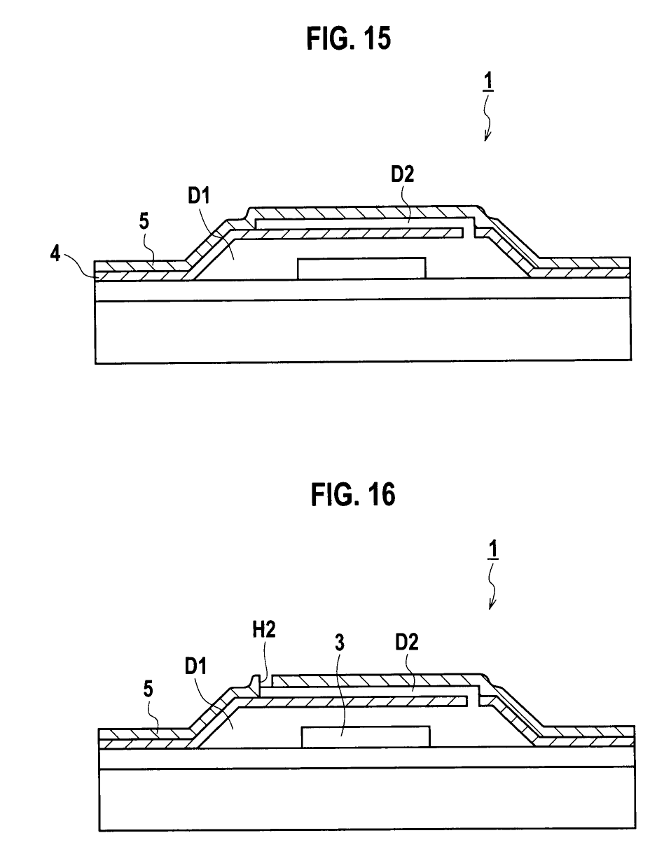

The second cap layer 5 is laminated so as to cover the whole surface of the second sacrificial layer D2 and the first cap layer 4, as shown in FIG. 15. The second cap layer 5 may be made of the same material as the first cap layer 4. Alternatively, the second cap layer 5 may be made of different material from the first cap layer 4.

Next, as shown in FIG. 16, a plurality of second through-holes H2 are formed, in the top board area F, in the second cap layer 5 in contact with the second sacrificial layer D2. Preferably, the second through-holes H2 are arranged as later-mentioned with reference to FIG. 19. Nevertheless, basically, the positioning of the second through-holes H2 is not limited to the illustrated embodiment and therefore, the second through-holes H2 have only to be formed in the second cap layer (part) 5 in the top board area 5. Additionally, the number of the second through-holes H2 may be either a singular number or a plural number.

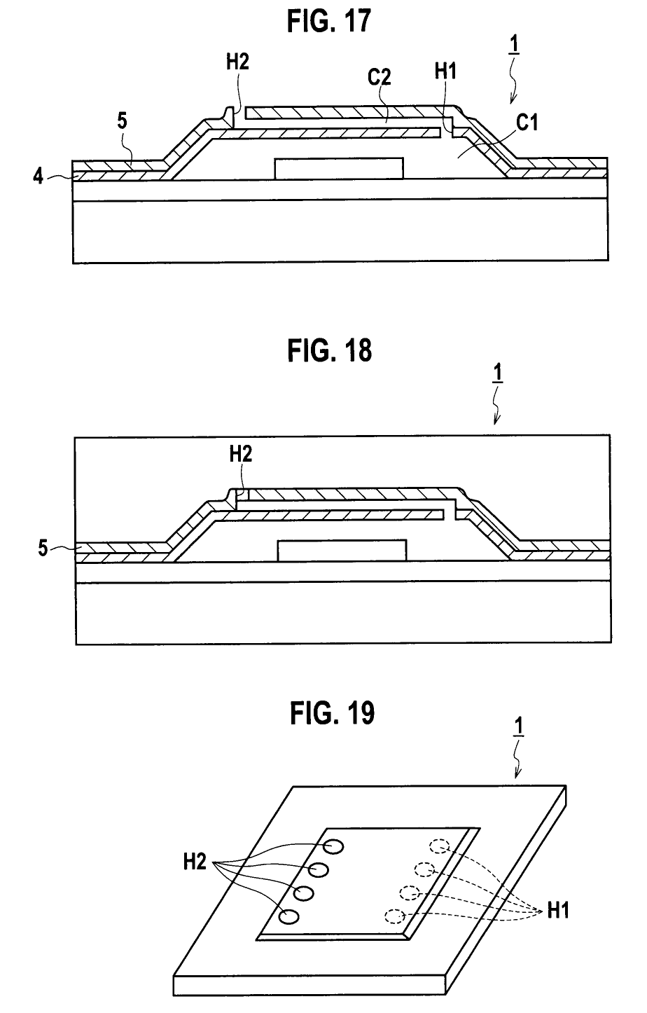

Next, as shown in FIG. 17, the first sacrificial layer D1 and the second sacrificial layer D2 are removed from the semiconductor device 1 by dry etching. The dry etching is performed through the use of the second through-holes H2 formed in the second cap layer 5 and the first through-holes H1 formed in the first cap layer 4. After the removal of the first sacrificial layer D1, the space C1 is formed in the semiconductor device 1. Similarly, after the removal of the second sacrificial layer D2, the hollow space C2 is formed in the semiconductor device 1. Subsequently, by closing up the second through-holes H2, the semiconductor device 1 of FIG. 9 is completed. Further, by using an appropriate molding die (not shown), resinous material is filled in a space above the second cap layer 5 so that the filled resinous material covers the whole surface of the second cap layer 5. In this way, the semiconductor device 1 shown in FIG. 18 is completed.

In the foregoing explanation, we described that the numbers of the first through-holes H1 and the second through-holes H2 may be either a singular number or a plural number each. However, the more the first through-holes H1 and the second through-holes H2 are formed, the shorter a time required to remove the first sacrificial layer D1 and the second sacrificial layer D2 becomes. As shown in FIG. 19, additionally, it is also preferable that the first through-holes H1 are respectively positioned so as to oppose the second through-holes H2 one on one, in plan view.

Before filling the resinous material in the molding die, the second through-holes H2 are clogged by sealant to seal up the spaces C1 and C2, as shown in FIG. 18. In connection with the above-mentioned arrangement where the first through-holes H1 are opposed to the second through-holes H2, it is preferable that the first and second through-holes H1, H2 are separated from each other, as possible. Because, if the first and second through-holes H1, H2 are close to each other, the sealant in clogging might reach the space C1 over the hollow space C2 and further progress to influence on the characteristics of the MEMS part 3 unfortunately.

Thus, even if pressure is applied on the cap layers 4, 5 in filling resinous material in the resin-molding process, it is possible to minimize the influence on the MEMS part 3 owing to the interposition of the hollow layer C2. Additionally, it is possible to prevent the characteristics of the MEMS part 3 from deteriorating with the sealing operation and also possible to ensure a normal operation of the MEMS part 3.

In detail, the pressure in filling the resinous material is applied on the second cap layer 5 and the first cap layer 4. In general, the pressure is applied on a cap layer's part in direct contact with the resinous material. Therefore, it might be expected that in the embodiment of the present invention, the pressure derived from the filling of resinous material is applied on only the second cap layer 5 in direct contact with the resinous material. However, it is noted that even the first cap layer's part (4) in direct contact with the second cap layer 5, such as the sidewall area E, is also subjected to pressure exerted on the second cap layer 5, namely, the pressure of the filled resinous material.

When the pressure is applied on the second cap layer (part) 5 in the top board area F, the second cap layer 5 comes under the influence of the pressure firstly, producing a deflection derived from to the applied pressure. However, owing to the presence of the hollow layer C2 between the second cap layer 5 and the first cap layer 4, the deflection of the second cap layer 5 is not transmitted to the first cap layer 4, producing no deflection. On the other hand, since the second cap layer (part) 5 makes direct contact with the first cap layer (part) 4 on both sides of the hollow layer C2, this contact area is subjected to pressure of the filled resinous material.

In this way, since the semiconductor device 1 of this embodiment has a cap part provided with the hollow layer C2, the pressure applied on the cap part in filling the resinous material (i.e. molding with resin) has no effect on the MEMS part 3 stored in the space C1, allowing the normal operation of the MEMS part 3 to be ensured.

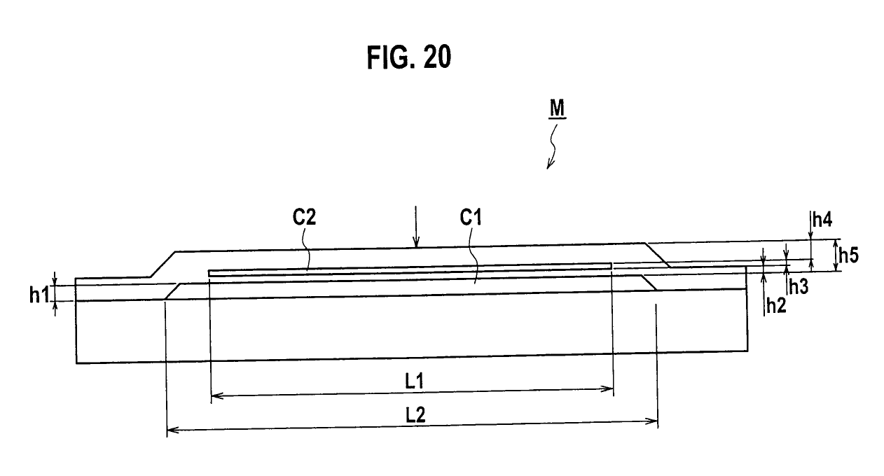

Besides, by inventors' calculation, it has been found that a deflection of the cap part with the hollow layer C2 is less than a deflection of the cap part without any hollow layer. FIG. 20 is a sectional view of one model of a semiconductor device used in the calculation by inventors. In the figure, the semiconductor device M is provided with the above-mentioned space C1 and the hollow layer C2, although the MEMS part is not illustrated.

Suppose, for the sake of convenience, a length of the hollow layer C2 is referred to as “cavity dimension” represented by L1. Additionally, a length of the space C1 where the semiconductor substrate abuts on the MEMS part (not shown) is referred to as “cap dimension” represented by L2. Assuming that as for various heights, h1 represents a height (vertical length) from the surface of the semiconductor substrate to one surface of the first cap layer in contact with the space C1, h2 a thickness of the first cap layer, h3 a height of the hollow layer C2, h4 a height of the second cap layer, and h5 represents a thickness of the cap part obtained by adding the first cap layer and the second cap layer. Numeric values used in the calculation are L1=400 μm, L2=500 μm, h1=17 μmm, h2=5 μm, h3=5 μm, h4=20 μm and h5=30 μm, respectively.

Suppose a situation that pressure is applied on the central part of the semiconductor device M (i.e. a midpoint of L2) in the direction arrow, as shown in FIG. 20. For the sake of convenience, it is assumed that a deflection in case of applying pressure on a semiconductor device M1 eliminating the hollow layer C2 is equal to 1 as a reference value. Then, the deflection in the semiconductor device M having the hollow layer C2 was 0.66 in relative displacement to the deflection (=1) of the semiconductor device M1. As can be understood, the smaller the value of relative displacement gets, the less the semiconductor device is deflected in comparison with the semiconductor device M1 as the reference. That is, it means that if the relative displacement is small, the semiconductor device is subjected to a small deflection. Therefore, it becomes apparent that under the same condition in terms of pressure applied on the cap part, the semiconductor device M having the hollow part C2 in the cap layers is deflected smaller than the semiconductor device M1 having no hollow part in the cap layers.

Using the above semiconductor device model, the inventors have analyzed which of settings in the length (cavity length: L1) of the hollow layer C2 could minimize such a deflection.

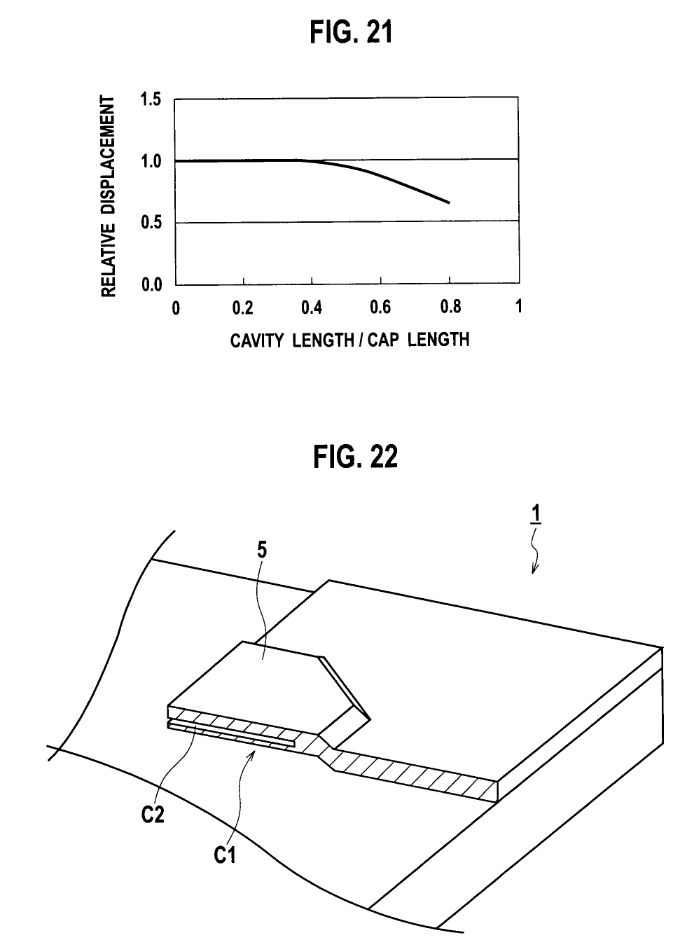

The result is as follows. FIG. 21 is a graph showing the relationship between the ratio of cavity length L1 to cap length L2 and the relative displacement. In the graph, a horizontal axis represents values about the ratio of cavity length L1/cap length L2, while a vertical axis represents the relative displacements of the semiconductor device M while setting the displacement of the semiconductor device M1 removing the hollow layer C2 to the reference value (=1.0). From the graph, it will be found that when exceeding 0.4 in the ratio of cavity length L1/cap length L2, the relative displacement decreases, although it trends to slightly decrease in the vicinity of 1.0 in the range from 0 up to 0.4 in the ratio of cavity length L1/cap length L2. This means that an amount of deflection gets smaller if the ratio of cavity length L1/cap length L2 exceeds 0.4 and that the amount of deflection can be minimized (i.e. 0.66) in case of 0.8 in the ratio of cavity length L1/cap length L2. If the ratio of cavity length L1/cap length L2 is more than 0.8, then the strength of the cap layers becomes unendurable to a filling pressure of resinous material. It follows that the most preferable situation could be realized in case of 0.8 in the ratio of cavity length L1/cap length L2.

In this way, owing to the provision of the hollow layer in the cap layers, it is possible to improve the productivity of a semiconductor device having a MEMS part with increased yield rate and also possible to provide a semiconductor device ensuring high reliability and a manufacturing method thereof.

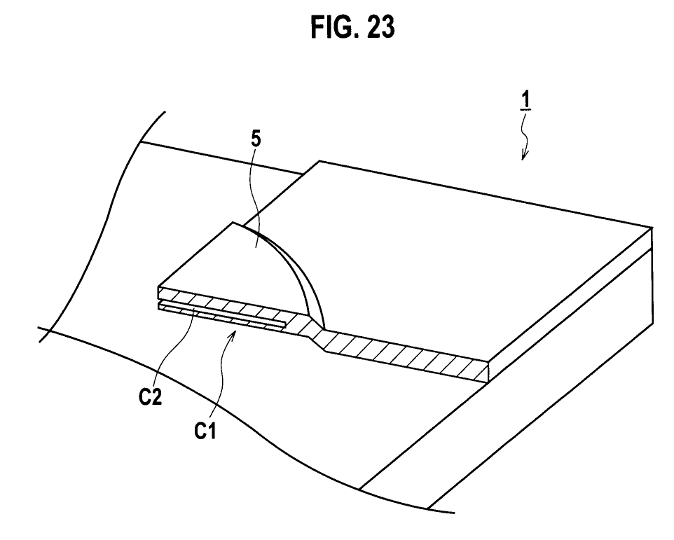

Although the present invention has been described above by reference to one embodiment of the invention, the invention is not limited to this and constituents may be modified within a scope of the essence of the present invention, in its execution phase. For instance, as shown in FIG. 22 or 23, the cap part may be shaped to be either polygonal or circular (including an oval shape) in plan view, although the cap part is square-shaped in plan view in the shown embodiment. Additionally, even if the cap part is shaped so as to make it difficult to distinguish between the sidewall area E and the top board area F (e.g. dome-shaped cap), the cap part has only to contain a hollow layer for absorbing pressure in filling resinous material. In this sense, an area containing such a hollow layer could be regarded as the top board area.

Furthermore, the present invention may be modified in various forms by combining the constituent disclosed in the above-mentioned embodiment with each other appropriately. In one form, for example, some constituents may be eliminated from all constituents shown in the embodiment. Alternatively, the present invention may be modified so as to combine constituents over different embodiments with each other appropriately.

This application is based upon the Japanese Patent Applications No. 2007-051309, filed on Mar. 1, 2007, the entire content of which is incorporated by reference herein.

What is claimed is:

1. A semiconductor device comprising:
a semiconductor substrate;
a MEMS part formed on a surface of the semiconductor substrate; and
a cap part arranged at a distance from the MEMS part and also arranged on the surface of the semiconductor substrate so as to cover the MEMS part;
wherein the cap part is formed by a sidewall area surrounding the MEMS part and a top board area having a hollow layer and also forming a closed space together with the semiconductor substrate and the sidewall area.

2. The semiconductor device of claim 1, wherein
the cap part includes a first cap layer opposed to the MEMS part at a distance and a second cap layer laminated on the first cap layer, and
the hollow layer is interposed between the first cap layer and the second cap layer.

3. A manufacturing method of a semiconductor device having a semiconductor substrate and a MEMS part formed on a surface of the semiconductor substrate, the method comprising the steps of:
forming a first sacrificial layer on the semiconductor substrate so as to cover both the MEMS part and a semiconductor substrate's part surrounding the MEMS part;
forming a first cap layer so as to cover the first sacrificial layer and a semiconductor substrate's part surrounding the first sacrificial layer;
forming at least one first through-hole in the first cap layer so as to penetrate the first cap layer and reach the first sacrificial layer;
forming a second sacrificial layer on the first cap layer so as to oppose the MEMS part through the intermediary of the first cap layer, the second sacrificial layer communicating with the first sacrificial layer through the first through-hole;
forming a second cap layer so as to cover the first cap layer and the second sacrificial layer;
forming at least one second through-hole in the second cap layer so as to penetrate the second cap layer and reach the second sacrificial layer;
removing the first sacrificial layer and the second sacrificial layer from the semiconductor device through the first through-hole and the second through-hole; and
clogging the second through-hole.

4. The manufacturing method of claim 3, wherein
the step of removing the first sacrificial layer and the second sacrificial layer is carried out by means of dry etching.

5. The manufacturing method of claim 3, further comprising a step of forming a resinous layer so as to cover the second cap layer.

6. The manufacturing method of claim 3, wherein
the at least one first through-hole comprises a plurality of first through-holes,
the at least one second through-hole comprises a plurality of first through-holes, and
the first through-holes are positioned so as to oppose the second through-holes, one on one in plan view.
